(19) United States
(12) Patent Application Publication
(10) Pub. No.: US 2011/0204465 A1
(43) Pub. Date: Aug. 25, 2011

(54) OPTICAL DEVICE AND METHOD OF MANUFACTURING THE DEVICE

(76) Inventor: Hu MENG, Osaka (JP)

(21) Appl. No.: 12/944,208

(22) Filed: Nov. 11, 2010

(30) Foreign Application Priority Data
Feb. 24, 2010 (JP) 2010-038844

(51) Int. Cl. H01L 31/02; H01L 31/18

(52) U.S. Cl. 257/434; 438/64; 257/E31.11

(57) ABSTRACT

In an optical device having a direct attachment structure and a method of manufacturing the optical device, a light-transmissive member can be bonded to an element region without being misaligned.

In the optical device, the element region is formed in a top surface of a semiconductor substrate. The light-transmissive member is bonded to the element region with a light-transmissive adhesive interposed therebetween. A dam portion is formed outside the element region on the top surface of the semiconductor substrate. A raised portion is formed on a top surface of the dam portion.

### CROSS-REFERENCE TO RELATED APPLICATION

This application claims priority to Japanese Patent Application No. 2010-038844 filed on Feb. 24, 2010, the disclosure of which including the specification, the drawings, and the claims is hereby incorporated by reference in its entirety.

### BACKGROUND

The present disclosure relates to an optical device including an image sensor such as a charge coupled device (CCD) and a complementary metal oxide semiconductor (CMOS), a light receiving element such as a photodiode, a phototransistor and a photo integrated circuit (IC), and a light-emitting element such as a light-emitting diode (LED) and a semiconductor laser; and a method of manufacturing the device.

In recent years, direct attachment structures have been proposed instead of conventional hollow package structures, for package structures of optical devices such as solid-state imaging devices (see, for example, Japanese Patent Publication No. H03-151666). FIG. 12 is a cross-sectional view illustrating a conventional solid-state imaging device having a direct attachment structure. In the solid-state imaging device shown in FIG. 12, a cap glass 101 is formed directly on an image sensor section 103 formed on a chip 102. The direct attachment structure refers to a structure in which a light-transmissive member is directly bonded to a light-receiving/light-emitting region provided on a semiconductor substrate by a light-transmissive adhesive. An advantage of the direct attachment structure is that the sensitivity of the optical device can be increased by making uniform the refractive indices of the light-transmissive member, the light-transmissive adhesive, and the light-transmissive film formed on the semiconductor substrate. Moreover, by employing the direct attachment structure, it is possible to more easily reduce the size and the thickness of the optical device, and to reduce mixture of dust into the light-receiving/light-emitting region during the manufacturing process, for example.

A solid-state imaging device having a direct attachment structure shown in FIG. 13 has also been proposed. FIG. 13 is a perspective view illustrating a conventional solid-state imaging device having a direct attachment structure. The solid-state imaging device shown in FIG. 13 includes a solid-state imaging element 211. In the solid-state imaging element 211, a light-receiving section 201 and electrode pads 207 are provided on the top surface of a semiconductor substrate 204. A light-transmissive member 202 is bonded to the light-receiving section 201 with a light-transmissive adhesive 210 interposed therebetween.

The solid-state imaging element 211, to which the light-transmissive member 202 is bonded, is provided on a substrate 208 including a plurality of leads 209.

The solid-state imaging device shown in FIG. 13 may have a problem as shown in FIGS. 14A and 14B. FIG. 14A is a top view illustrating the problem of the conventional solid-state imaging device. FIG. 14B is a cross-sectional view taken along line XIVb-XIVb of FIG. 14A.

As shown in FIGS. 14A and 14B, when the light-transmissive member 202 is provided on the semiconductor substrate 204 with the light-transmissive adhesive 210 interposed therebetween, the light-transmissive adhesive 210 may flow over the edge of the light-transmissive member 202 as viewed from above so as to adhere to the electrode pads 207. (The electrode pads 207 are provided in a peripheral portion of the top surface of the semiconductor substrate 204.)

In view of this problem, a solid-state imaging device shown in, for example, FIGS. 15, 16A and 16B has been proposed (see, for example, Japanese Patent Publication No. 2007-150266). FIG. 15 is a perspective view illustrating the configuration of the conventional solid-state imaging device. FIG. 16A is a top view illustrating the configuration of the conventional solid-state imaging device. FIG. 16B is a cross-sectional view taken along line XVIb-XVIb of FIG. 16A. In the solid-state imaging device shown in FIGS. 15, 16A and 16B, a flattening film 203 including raised portions 206 is formed on a semiconductor substrate 204. The raised portions 206 extend between a light-receiving section 201 and electrode pads 207 as viewed from above. The raised portions 206 reduce flow of a light-transmissive adhesive 210 into the electrode pads 207.

A solid-state imaging device shown in FIGS. 17, 18A and 18B has been proposed (see, for example, Japanese Patent Publication No. 2009-135401). FIG. 17 is a perspective view illustrating the configuration of the conventional solid-state imaging device. FIG. 18A is a top view illustrating the configuration of the conventional solid-state imaging device. FIG. 18B is a cross-sectional view taken along line XVIIIb-XVIIIb of FIG. 18A. In the solid-state imaging device shown in FIGS. 17, 18A and 18B, a flattening film 203 including raised portions 216 is formed on a semiconductor substrate 204. The raised portions 216 extend between a light-receiving section 201 and electrode pads 207 as viewed from above. The raised portions 216 reduce flow of a light-transmissive adhesive 210 into the electrode pads 207.

Furthermore, a solid-state imaging device shown in FIGS. 19, 20A and 20B has been proposed (see, for example, Japanese Patent Publication No. 2009-239258). FIG. 19 is a perspective view illustrating the configuration of the conventional solid-state imaging device. FIG. 20A is a top view illustrating the configuration of the conventional solid-state imaging device. FIG. 20B is a cross-sectional view taken along line XXb-XXb of FIG. 20A. In the solid-state imaging device shown in FIGS. 19, 20A and 20B, a flattening film 203 including recessed portions 225 is formed on a semiconductor substrate 204. The recessed portions 225 extend between a light-receiving section 201 and electrode pads 207 as viewed from above. The recessed portions 225 reduce flow of a light-transmissive adhesive 210 into the electrode pads 207.

### SUMMARY

When manufacturing the conventional solid-state imaging devices shown in FIGS. 12-20B, the light-transmissive adhesive 210 is applied onto the semiconductor substrate 204, and then, the light-transmissive member 202 is provided on the light-transmissive adhesive 210. After that, the light-transmissive adhesive 210 is cured by ultraviolet (UV) radiation. Thus, the solid-state imaging device during the manufacturing process is transferred to a UV curing unit. At this time, the light-transmissive member 202 may be misaligned with respect to the light-receiving section 201 due to vibration of the transfer device and the like (see FIGS. 21A and 21B). FIG. 21A is a top view illustrating a problem of a conventional solid-state imaging device. FIG. 21B is a cross-sectional view taken along line XXIb-XXIb of FIG. 21A. Such a problem may result in a decrease in light-collecting efficiency due to reflection loss.

Furthermore, when the problem shown in FIGS. 21A and 21B occurs in a light-emitting device including a light-emitting element, part of light emitted from the light-emitting element is not picked up outside the light-emitting device. This causes a decrease in luminous efficiency.

The present disclosure was made in view of the problems. It is an objective of the present disclosure to provide an optical device having a direct attachment structure with a reduced size and desirable performance, and a method of manufacturing the device.

In an optical device according to the present disclosure, an element region (including at least one of a light-receiving region and a light-emitting region) is formed on a semiconductor substrate. A light-transmissive board is bonded to the element region with a light-transmissive adhesive interposed therebetween. At least one dam portion is formed outside the element region. The light-transmissive board is mounted on the dam portion. A raised portion is formed on the dam portion. This reduces misalignment of the light-transmissive board with respect to the element region during the manufacturing process of the optical device, for example.

The raised portion may be fitted within a trench formed in a bottom surface of the light-transmissive board.

A side surface of the light-transmissive board is preferably arranged inside the raised portion, and preferably abuts on a side surface of the raised portion. The raised portion preferably has an L shape as viewed from above. This efficiently reduces misalignment of the light-transmissive board.

The at least one dam portion may include at least two dam portions provided on the semiconductor substrate. The two dam portions are preferably diagonally arranged on the semiconductor substrate as viewed from above. This facilitates determination of the position of the light-transmissive board with respect to the element region.

In the following preferable embodiments, an electrode pad is formed outside the element region on the semiconductor substrate. The dam portion is provided between the element region and the electrode pad on the semiconductor substrate.

In a method of manufacturing an optical device according to the present disclosure, an element region is formed on a semiconductor substrate, a dam portion is formed outside the element region, and a light-transmissive board is bonded to the element region with a light-transmissive resin interposed therebetween. A raised portion is formed on the dam portion.

The raised portion is preferably fitted within a trench formed in a bottom surface of the light-transmissive board.

A side surface of the light-transmissive board is preferably arranged inside the raised portion, and preferably abuts on a side surface of the raised portion.

The at least one dam portion may include at least two dam portions provided on the semiconductor substrate. The two dam portions are preferably diagonally arranged on the semiconductor substrate as viewed from above.

In the following preferable embodiments, the light-transmissive resin is cured.

According to the optical device and the method of manufacturing the device according to the present disclosure, the light-transmissive board is directly bonded to the semiconductor substrate without being misaligned with respect to the element region. Therefore, in the present disclosure, sensitivity of an optical device can be improved and the optical device can be miniaturized.

### BRIEF DESCRIPTION OF THE DRAWINGS

FIG. 1 is a perspective view illustrating a configuration of a solid-state imaging device according to a first embodiment of the present disclosure.

FIG. 2A is a top view illustrating the configuration of the solid-state imaging device according to the first embodiment.

FIG. 2B is a cross-sectional view taken along line IIb-IIb of FIG. 2A.

FIG. 3 is a flow chart illustrating a method of manufacturing the solid-state imaging device according to the first embodiment.

FIGS. 4A-4E are cross-sectional views illustrating steps in the method of manufacturing the solid-state imaging device according to the first embodiment.

FIG. 5A is a top view illustrating a configuration of a solid-state imaging device according to a second embodiment.

FIG. 5B is a cross-sectional view taken along line Vb-Vb of FIG. 5A.

FIG. 6 is a flow chart illustrating a method of manufacturing the solid-state imaging device according to the second embodiment.

FIG. 7A is a top view illustrating a configuration of a solid-state imaging device according to a third embodiment.

FIG. 7B is a cross-sectional view taken along line VIIb-VIIb of FIG. 7A.

FIG. 8A is a top view illustrating a configuration of a solid-state imaging device according to a fourth embodiment.

FIG. 8B is a cross-sectional view taken along line VIIIb-VIIIb of FIG. 8A.

FIG. 9A is a top view illustrating a configuration of an LED according to a fifth embodiment.

FIG. 9B is a cross-sectional view taken along line IXb-IXb of FIG. 9A.

FIG. 10A is a top view illustrating the configuration of the main part of the LED shown in FIG. 9A.

FIG. 10B is a cross-sectional view taken along line Xb-Xb of FIG. 10A.

FIG. 11A is a top view illustrating a configuration of a solid-state imaging device according to a sixth embodiment.

FIG. 11B is a cross-sectional view taken along line XIb-XIb of FIG. 11A

FIG. 12 is a cross-sectional view illustrating a configuration of a first conventional solid-state imaging device.

FIG. 13 is a perspective view illustrating a configuration of a second conventional solid-state imaging device.

FIG. 14A is a top view illustrating a problem of the second conventional solid-state imaging device.

FIG. 14B is a cross-sectional view taken along line XIVb-XIVb of FIG. 14A.

FIG. 15 is a perspective view illustrating a configuration of a third conventional solid-state imaging device.

FIG. 16A is a top view illustrating the third conventional solid-state imaging device.

FIG. 16B is a cross-sectional view taken along line XVIb-XVIb of FIG. 16A.

FIG. 17 is a perspective view illustrating a configuration of a fourth conventional solid-state imaging device.

FIG. 18A is a top view illustrating the fourth conventional solid-state imaging device.

FIG. 18B is a cross-sectional view taken along line XVIIIb-XVIIIb of FIG. 18A.

FIG. 19 is a perspective view illustrating a configuration of a fifth conventional solid-state imaging device.

FIG. 20A is a top view illustrating the fifth conventional solid-state imaging device.

FIG. 20B is a cross-sectional view taken along line XXb-XXb of FIG. 20A.

FIG. 21A is a top view illustrating a problem of the conventional solid-state imaging devices.

FIG. 21B is a cross-sectional view taken along line XXIb-XXIb of FIG. 21A.

### DETAILED DESCRIPTION

Embodiments of the present disclosure will be described hereinafter in detail with reference to the drawings. Note that the present disclosure is not limited to the following embodiments.

### First Embodiment

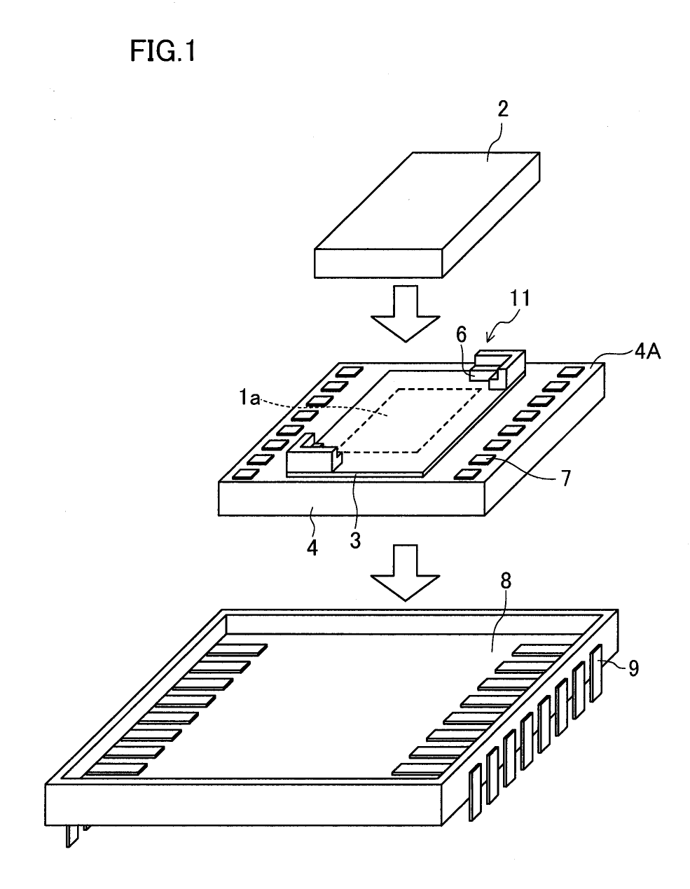

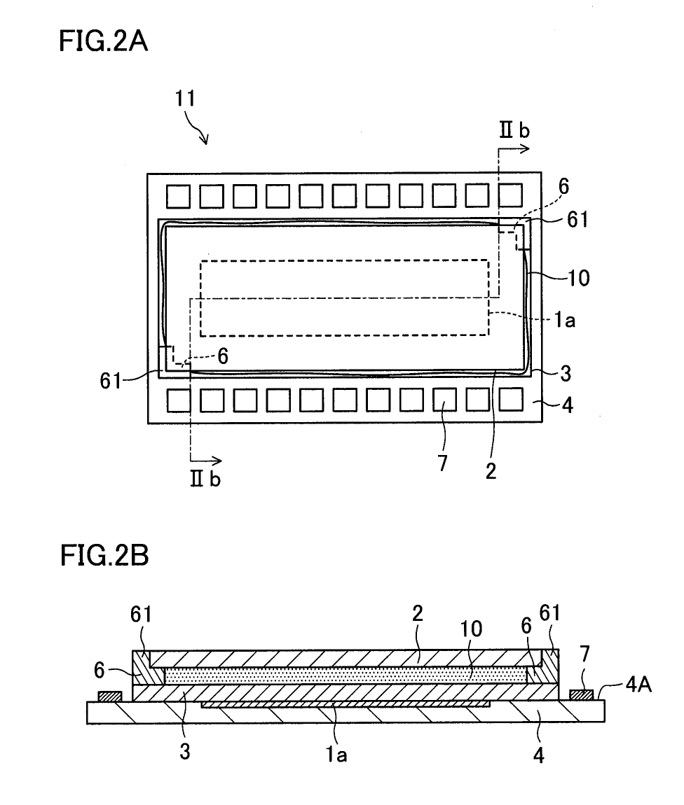

In a first embodiment of the present disclosure, a solid-state imaging device will be described as an example of an optical device. FIG. 1 is a perspective view illustrating the configuration of the solid-state imaging device according to this embodiment. FIG. 2A is a top view illustrating the configuration of the solid-state imaging device according to this embodiment. FIG. 2B is a cross-sectional view taken along line IIb-IIb of FIG. 2A.

As shown in FIGS. 1, 2A, and 2B, in the solid-state imaging device according to this embodiment, a solid-state imaging element 11 is provided on a package substrate 8 including a plurality of leads 9. The solid-state imaging element 11 includes a semiconductor substrate 4 having a top surface 4A provided with a light-receiving region (element region) 1a, a plurality of electrode pads 7 provided in a peripheral portion of the top surface 4A of the semiconductor substrate 4, and a light-transmissive insulating film 3 provided on the light-receiving region 1a. A light-transmissive member (light-transmissive board) 2 is bonded to the light-receiving region 1a of the solid-state imaging element 11 with a light-transmissive adhesive layer 10 interposed therebetween.

In the solid-state imaging device according to this embodiment, dam portions 6 are provided on the light-transmissive insulating film 3. The dam portions 6 are provided outside the light-receiving region 1a, and inside the electrode pads 7 on the top surface 4A of the semiconductor substrate 4. The dam portions 6 are arranged on the top surface 4A of the semiconductor substrate 4 to interpose the light-receiving region 1a. Specifically, the dam portions 6 are provided on corners of the light-transmissive insulating film 3, which are diagonally located with respect to the light-receiving region 1a.

Each of the dam portions 6 is formed in an L shape as viewed from above. Raised portions 61 are provided on the top surfaces of the dam portions 6 at the side of the peripheral portion of the top surface 4A of the semiconductor substrate 4. Each of the raised portions 61 is located higher than the bottom surface of the light-transmissive member 2, and is formed in an L shape as viewed from above. The corners of the raised portions 61 abut on corners of the light-transmissive member 2. That is, the position of the light-transmissive member 2 is determined by the raised portions 61 of the dam portions 6. This enables the light-transmissive member 2 to be bonded to the semiconductor substrate 4 without being misaligned with respect to the light-receiving region 1a. Therefore, in this embodiment, a solid-state imaging device having a high sensitive and high performance direct attachment structure can be realized, since a decrease in light-collecting efficiency due to reflection loss and the like can be mitigated.

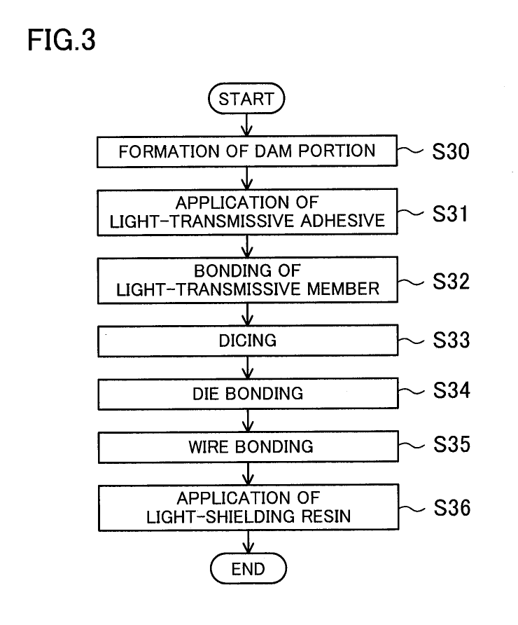

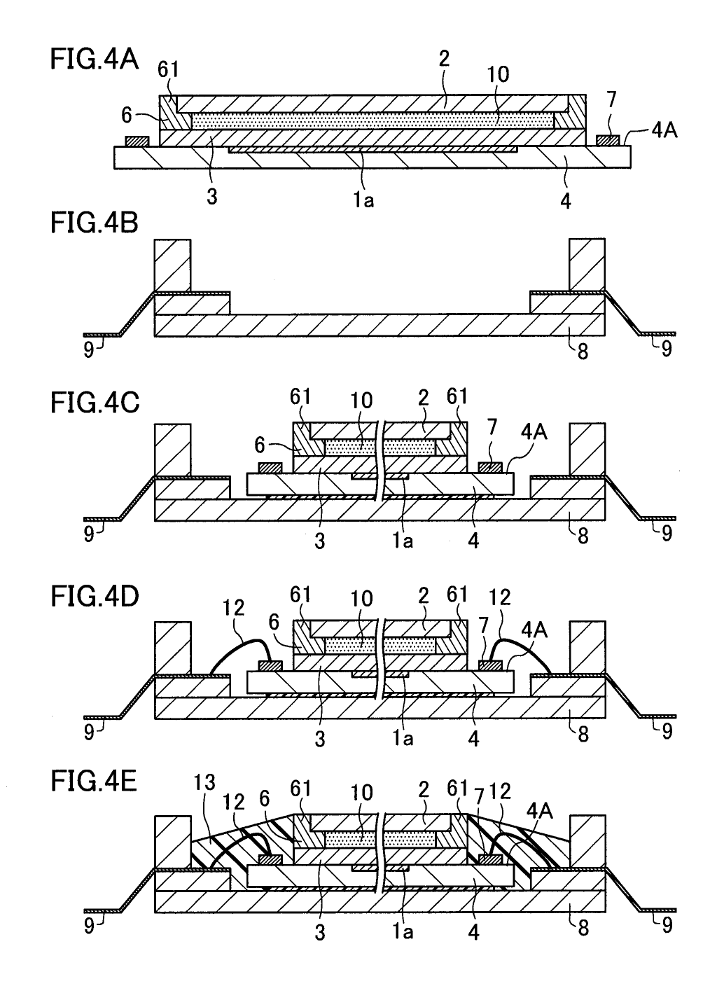

Next, a method of manufacturing the solid-state imaging device according to this embodiment will be described below with reference to FIGS. 3, and 4A-4E. FIG. 3 is a flow chart illustrating the method of manufacturing the solid-state imaging device of this embodiment. FIGS. 4A-4E are cross-sectional views illustrating steps in the method of manufacturing the solid-state imaging device according to this embodiment.

In the manufacturing method of the solid-state imaging device according to this embodiment, although it is not shown, a semiconductor wafer segmented into a plurality of regions by dicing lines is prepared. The light-receiving region 1a is formed in each of the regions. The electrode pads 7 are formed outside the light-receiving region 1a in each of the regions. The light-transmissive insulating film 3 is formed on the light-receiving region 1a.

Next, in a step S30, the dam portions 6 are formed in each of the regions of the semiconductor wafer.

Specifically, the dam portions 6, each of which is made of a photosensitive material etc., is formed on the light-transmissive insulating film 3 and between the light-receiving region 1a and the electrode pads 7 as viewed from above. As a specific formation method of the dam portions 6, the photosensitive material such as acrylate is applied onto the Light-transmissive insulating film 3 to form an acrylate mask. Next, a part of the photosensitive material other than the formation regions of the dam portions 6 is selectively removed by photography using the acrylate mask as a mask. As such, the dam portions 6 are formed. The dam portions 6 are provided on corners of the light-transmissive insulating film 3, which are diagonally located with respect to the light-receiving region 1a, and include the raised portions 61 on the top surfaces.

Then, in a step S31, a light-transmissive liquid adhesive is supplied to the regions of the semiconductor wafer.

After that, in a step S32, the light-transmissive member 2 is provided on the light-transmissive adhesive to cover the light-receiving region 1a. At this time, the corners of the light-transmissive member 2 abut on the comers of the raised portions 61 of the dam portions 6. Then, the light-transmissive adhesive is cured by UV radiation. As such, the light-transmissive member 2 is bonded to the light-transmissive insulating film 3.

Next, in a step S33, the semiconductor wafer is diced, to which the light-transmissive members 2 are bonded. As such, a plurality of solid-state imaging elements are formed (see FIG. 4A).

Then, in a step S34, the package substrate 8 provided with the plurality of leads 9 is prepared as shown in FIG. 4B. After that, as shown in FIG. 4C, the separated solid-state imaging elements are mounted on the package substrate 8 by die bonding.

Thereafter, in a step S35, the leads 9 are wire bonded to the respective electrode pads 7 with wires 12, as shown in FIG. 4B.

After that, in a step S36, a light-shielding adhesive 13 is applied onto a region of the semiconductor substrate 4 other than the upper surface of the light-transmissive member 2, as shown in FIG. 4E. As such, the solid-state imaging element is packaged and the solid-state imaging device according to this embodiment is manufactured.

In the method of manufacturing the solid-state imaging device according to this embodiment, the dam portions 6 are formed in the step S30, and the corners of the light-transmissive member 2 abut on the raised portions 61 of the dam portions 6 in the step S32. This reduces misalignment of the light-transmissive member 2 with respect to the light-receiving region 1a due to vibration and the like, when the solid-state imaging device during the manufacturing process is transferred to a UV curing unit in the step S32. This mitigates a decrease in light-collecting efficiency due to reflection loss and the like in the manufactured solid-state imaging device. In addition, the light-transmissive member 2 is prevented from being bonded to the light-transmissive adhesive while covering the upper portions of the dicing lines, and thus, dicing can be smoothly performed in the step S33. Moreover, the light-transmissive member 2 is prevented from being bonded to the light-transmissive adhesive while covering the electrode pads 7, and thus, wire bonding can be smoothly performed in the step S35.

Also, in the method of manufacturing the solid-state imaging device according to this embodiment, a solid-state imaging device having a direct attachment structure and being packaged by resin sealing in the steps shown in FIGS. 4A-4E can be obtained. This reduces the problems such as mixing of dust into the light-receiving region 1a during the manufacturing process. Therefore, a highly reliable solid-state imaging device can be realized by the manufacturing method of the solid-state imaging device according to this embodiment.

Note that the solid-state imaging device according to this embodiment may have the following configuration.

The dam portions 6 may be provided on corners of the light-transmissive insulating film 3, which are adjacent to each other. However, when the dam portions 6 are provided on the corners of the light-transmissive insulating film 3, which are diagonally located with respect to the light-receiving region 1a, the position of the light-transmissive member 2 can be easily determined to further reduce misalignment of the light-transmissive member 2. Therefore, the dam portions 6 are preferably provided on the corners of the light-transmissive insulating film 3, which are diagonally located with respect to the light-receiving region 1a. This feature is applicable to the second embodiment below, and the fifth and sixth embodiments described later.

The number of the dam portions 6 is not limited to two. For example, when the dam portions 6 are provided near the corners of the light-transmissive member 2, misalignment of the light-transmissive member 2 can be further reduced, since the corners of the light-transmissive member 2 abut on the raised portions 61 of the dam portions 6. This feature is applicable to the second embodiment below, and the fifth and sixth embodiments described later.

The light-transmissive insulating film 3 may or may not be provided. When the light-transmissive insulating film 3 is not provided, the dam portions 6 may be provided on the principal surface 4A of the semiconductor substrate 4. This alternative is applicable to the second embodiment below, and the third to sixth embodiments described later.

### Second Embodiment

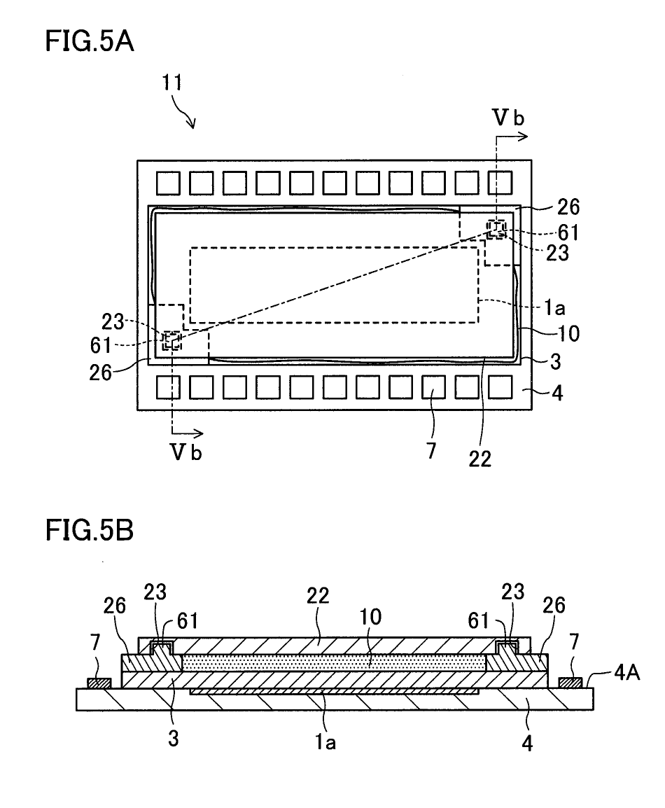

In a second embodiment of the present disclosure, a solid-state imaging device will be described as an example of an optical device. FIG. 5A is a top view illustrating the configuration of the solid-state imaging device according to this embodiment. FIG. 5B is a cross-sectional view taken along line Vb-Vb of FIG. 5A. This embodiment differs from the first embodiment in the shapes of the dam portions and the light-transmissive member.

As shown in FIGS. 5A and 5B, in the solid-state imaging device according to this embodiment, a solid-state imaging element 11 is provided on a package substrate 8 including a plurality of leads 9. The solid-state imaging element 11 includes a semiconductor substrate 4 having a top surface 4A provided with a light-receiving region 1a, a plurality of electrode pads 7 provided in a peripheral portion of the top surface 4A of the semiconductor substrate 4, and a light-transmissive insulating film 3 provided on the light-receiving region 1a. A light-transmissive member 22 is bonded to the light-receiving region 1a of the solid-state imaging element 11 with a light-transmissive adhesive layer 10 interposed therebetween.

In the solid-state imaging device according to this embodiment, dam portions 26 are provided on the light-transmissive insulating film 3. The dam portions 26 are provided outside the light-receiving region 1a, and inside the electrode pads 7 on the top surface 4A of the semiconductor substrate 4. The dam portions 6 are arranged on the top surface 4A of the semiconductor substrate 4 to interpose the light-receiving region 1a. Specifically, the dam portions 26 are provided on corners of the light-transmissive insulating film 3, which are diagonally located with respect to the light-receiving region 1a.

Each of the dam portions 26 is formed in an L shape as viewed from above. Raised portions 61 are provided on the top surfaces of the dam portions 26. Each of the raised portions 61 is fitted into a trench 23 formed in the bottom surface of the light-transmissive member 22. That is, the position of the light-transmissive member 22 is determined by the raised portions 61 of the dam portions 26. This enables the light-transmissive member 22 to be bonded to the semiconductor substrate 4 without being misaligned with respect to the light-receiving region 1a. Therefore, in this embodiment, a solid-state imaging device having a high sensitive and high performance direct attachment structure can be realized, since a decrease in light-collecting efficiency due to reflection loss and the like can be mitigated.

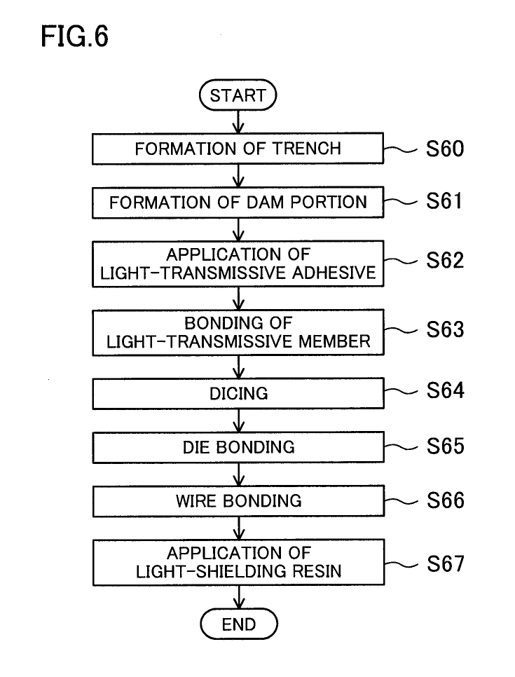

Next, a method of manufacturing the solid-state imaging device according to this embodiment will be described below with reference to FIG. 6. FIG. 6 is a flow chart illustrating the method of manufacturing the solid-state imaging device according to this embodiment.

First, the semiconductor wafer described in the first embodiment is prepared.

Next, in a step S60, the trenches 23 are formed in the light-transmissive member 22. As the formation method of the trenches 23, the trenches 23 are formed with an industrial cutting tool such as a carbide drill or a diamond drill while applying liquid such as water or oil to the light-transmissive member 22.

Then, in a step S61, the dam portions 26 are formed in regions in the semiconductor wafer. Specifically, the dam portions 26, each of which is made of a photosensitive material etc., are formed on the light-transmissive insulating film 3 and between the light-receiving region 1a and the electrode pads 7 as viewed from above. As a specific formation method of the dam portions 26, the photosensitive material such as acrylate is applied onto the light-transmissive insulating film 3 to form an acrylate mask. Next, a part of the photosensitive material other than the formation regions of the dam portions 26 is selectively removed by photography using the acrylate mask as a mask. As such, the dam portions 26 are formed. The dam portions 26 are provided on corners of the light-transmissive insulating film 3, which are diagonally located with respect to the light-receiving region 1a, and include the raised portions 61 on the top surfaces.

Then, in a step S62, a light-transmissive liquid adhesive is supplied to the regions of the semiconductor wafer.

After that, in a step S63, the light-transmissive member 22 is provided on the light-transmissive adhesive to cover the light-receiving region 1a. At this time, the raised portions 61 of the dam portions 26 are fitted into the trenches 23 in the light-transmissive member 22. Then, the light-transmissive adhesive is cured by UV radiation. As such, the light-transmissive member 22 is bonded to the light-transmissive insulating film 3.

Next, in a step S64, the semiconductor wafer is diced, to which the light-transmissive members 22 are bonded. As a result, a plurality of solid-state imaging elements 11 are formed, to which the light-transmissive members 22 are bonded.

Then, in a step S65, the package substrate 8 provided with the plurality of leads 9 is prepared. After that, the separated solid-state imaging elements 11 are mounted on the package substrate 8 by die bonding.

Thereafter, in a step S66, the leads 9 are wire bonded to the respective electrode pads 7 with wires 12.

After that, in a step S67, a light-shielding adhesive 13 is applied onto a region of the semiconductor substrate 4 other than the upper surfaces of the light-transmissive member 22. As such, the solid-state imaging element 11 is packaged and the solid-state imaging device according to this embodiment is manufactured.

In the method of manufacturing the solid-state imaging device according to this embodiment, the trenches 23 are formed in the light-transmissive member 22 in the step S60, the dam portions 26 are formed in the step S61, and the raised portions 61 of the dam portions 26 are fitted into the trenches 23 of the light-transmissive member 22 in the step S63. This reduces misalignment of the light-transmissive member 22 with respect to the light-receiving regions 1a due to vibration and the like, when the solid-state imaging device during the manufacturing process is transferred to a UV curing unit in the step S63. This mitigates a decrease in light-collecting efficiency due to reflection loss and the like in the manufactured solid-state imaging device. In addition, the light-transmissive member 22 is prevented from being bonded to the light-transmissive adhesive while covering the upper portions of the dicing lines, and thus, dicing can be smoothly performed in the step S64. Moreover, the light-transmissive member 22 is prevented from being bonded to the light-transmissive adhesive while covering the electrode pads 7, and thus, wire bonding can be smoothly performed in the step S66.

Also, in the method of manufacturing the solid-state imaging device according to this embodiment, a solid-state imaging device having a direct attachment structure and being packaged by resin sealing can be obtained. This reduces the problems such as mixing of dust into the light-receiving regions la during the manufacturing process. Therefore, a highly reliable solid-state imaging device can be realized by the manufacturing method of the solid-state imaging device according to this embodiment.

### Third Embodiment

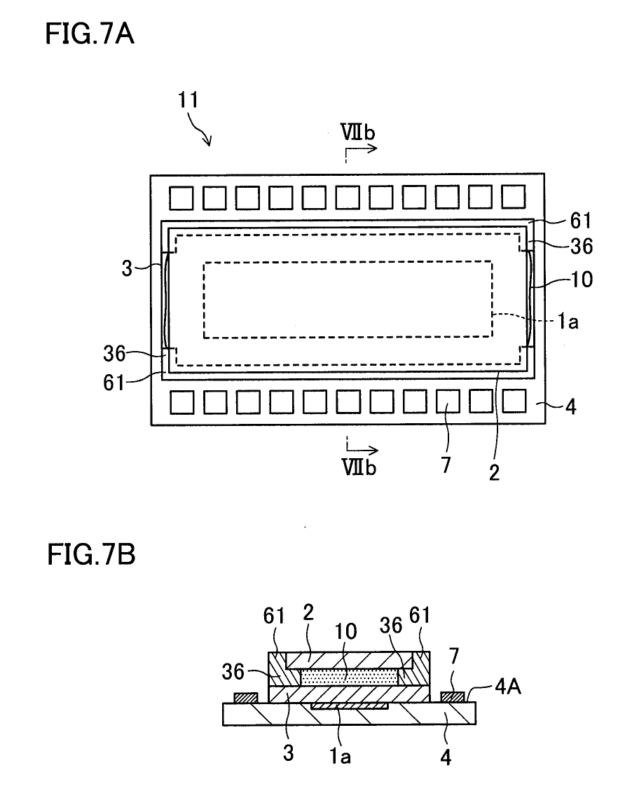

In a third embodiment of the present disclosure, a solid-state imaging device will be described as an example of an optical device. FIG. 7A is a top view illustrating the configuration of the solid-state imaging device according to this embodiment. FIG. 7B is a cross-sectional view taken along line VIIb-VIIb of FIG. 7A. This embodiment differs from the first embodiment in the shapes of the dam portions. The features different from the first embodiment will be mainly described below.

As shown in FIGS. 7A and 7B, in the solid-state imaging device according to this embodiment, a solid-state imaging element 11 is provided on a package substrate 8 including a plurality of leads 9. The solid-state imaging element 11 includes a semiconductor substrate 4 having a top surface 4A provided with a light-receiving region 1a, a plurality of electrode pads 7 provided in a peripheral portion of the top surface 4A of the semiconductor substrate 4, and a light-transmissive insulating film 3 provided on the light-receiving region 1a. A light-transmissive member 2 is bonded to the light-receiving region 1a of the solid-state imaging element 11 with a light-transmissive adhesive layer 10 interposed therebetween.

In the solid-state imaging device according to this embodiment, dam portions 36 are provided on the light-transmissive insulating film 3. The dam portions 36 correspond to the dam portions 6 in the first embodiment, and are formed to extend along a line on which the electrode pads 7 are aligned. Thus, corners of the raised portions 61 of the dam portions 36 abut on corners of the light-transmissive member 2. The part other than the corners of the raised portions 61 of the dam portions 36 abuts on the part of the light-transmissive member 2 extending along the alignment of the electrode pads 7.

In this embodiment, the following advantages can be obtained in addition to the advantages obtained in the first embodiment. Even if a relatively large amount of light-transmissive adhesive spreads toward the peripheral portion of the top surface 4A of the semiconductor substrate 4 when the light-transmissive member 2 is pressed onto the light-transmissive adhesive to be fixed, the dam portions 36 reduce flow of the light-transmissive adhesive onto the electrode pads 7. Therefore, smooth electrical connection can be realized between the electrode pads 7 and the leads 9 of the package substrate 8.

Note that the dam portions 36 may extend in a direction perpendicular to the alignment of the electrode pads 7 (in a vertical direction in FIG. 7A). However, when the dam portions 36 extend along the alignment of the electrode pads 7, the spread of an excessive light-transmissive adhesive toward the electrode pads 7 can be reduced. Therefore, the dam portions 36 preferably extend in a direction parallel to the alignment of the electrode pads 7.

### Fourth Embodiment

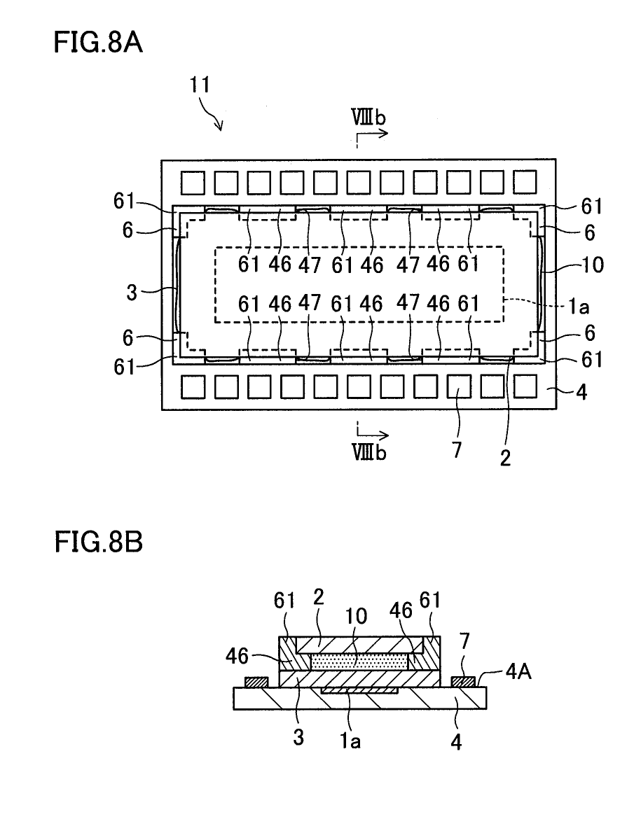

In a fourth embodiment of the present disclosure, a solid-state imaging device will be described as an example of an optical device. FIG. 8A is a top view illustrating the configuration of the solid-state imaging device according to this embodiment. FIG. 8B is a cross-sectional view taken along line VIIIb-VIIIb of FIG. 8A. This embodiment differs from the first embodiment in the shapes of the dam portions. The features different from the first embodiment will be mainly described below.

As shown in FIGS. 8A and 8B, in the solid-state imaging device according to this embodiment, a solid-state imaging element 11 is provided on a package substrate 8 including a plurality of leads 9. The solid-state imaging element 11 includes a semiconductor substrate 4 having a top surface 4A provided with a light-receiving region 1a, a plurality of electrode pads 7 provided in a peripheral portion of the top surface 4A of the semiconductor substrate 4, and a light-transmissive insulating film 3 provided on the light-receiving region 1a. A light-transmissive member 2 is bonded to the light-receiving region 1a of the solid-state imaging element 11 with a light-transmissive adhesive layer 10 interposed therebetween.

In the solid-state imaging device according to this embodiment, dam portions 46 are provided on the light-transmissive insulating film 3 in addition to the dam portions 6 described in the first embodiment. The dam portions 46 are provided along the alignment of the electrode pads 7 with spaces 47 interposed therebetween, and have rectangle shapes as viewed from above. Furthermore, raised portions 61 are formed on the top surfaces of the dam portions 46 at the side of the peripheral portion of the top surface 4A of the semiconductor substrate 4. Therefore, in this embodiment, corners of the light-transmissive member 2 abut on corners of the raised portions 61 of the dam portions 6, and the raised portions 61 of the dam portions 46 abut on a part of the light-transmissive member 2 extending along the alignment of the electrode pads 7.

In this embodiment, the following advantages can be obtained in addition to the advantages obtained in the first embodiment. If a relatively large amount of light-transmissive adhesive spreads toward the peripheral portion of the top surface 4A of the semiconductor substrate 4, when the light-transmissive member 2 is pressed onto the light-transmissive adhesive to be fixed, the light-transmissive adhesive enters the spaces 47. Then, surface tension applied to the light-transmissive adhesive reduces flow of the light-transmissive adhesive spreading toward the peripheral portion of the top surface 4A of the semiconductor substrate 4 onto the electrode pads 7. Therefore, smooth electrical connection can be realized between the electrode pads 7 and the leads 9 of the package substrate 8.

Note that the dam portions 46 may be provided in a direction perpendicular to the alignment of the electrode pads 7 (in a vertical direction in FIG. 8A) with spaces interposed therebetween. However, when the dam portions 46 extend along the alignment of the electrode pads 7 with the spaces 47 interposed therebetween, the spread of an excessive Light-transmissive adhesive toward the electrode pads 7 can be reduced. Therefore, the dam portions 46 preferably extend along the alignment of the electrode pads 7 with the spaces 47 interposed therebetween.

### Fifth Embodiment

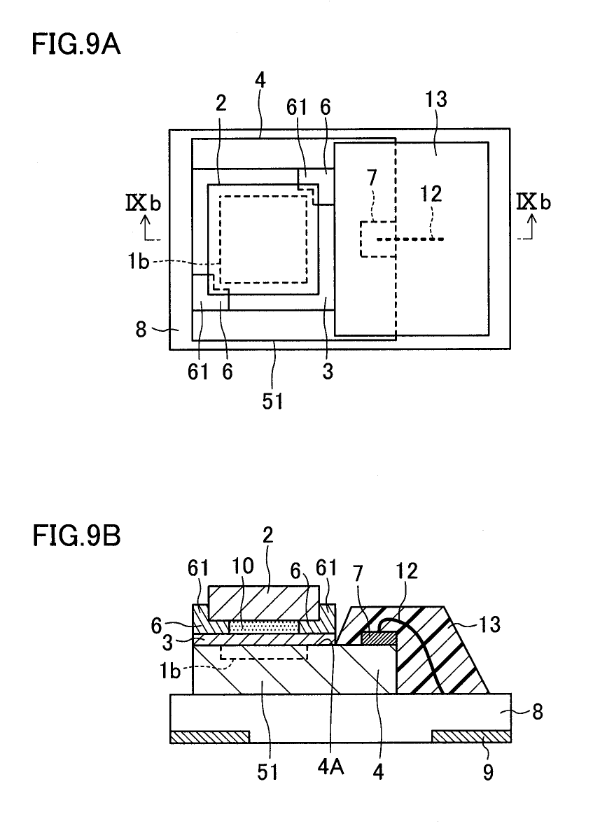

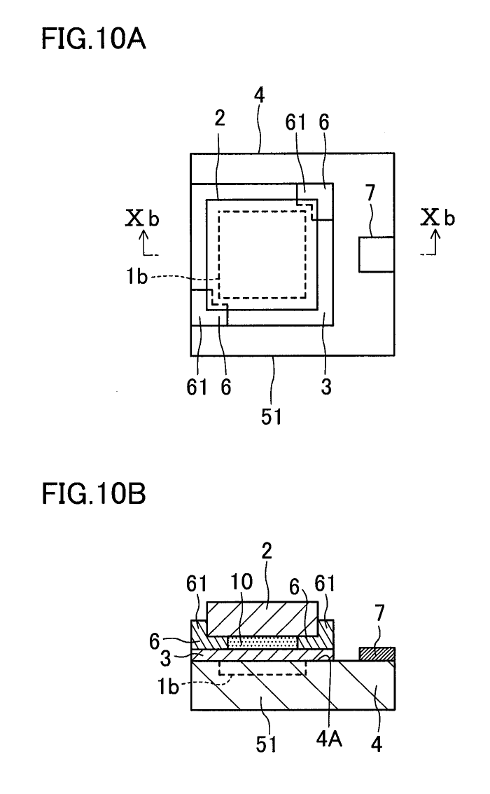

In a fifth embodiment of the present disclosure, a light-emitting diode (LED) will be described as an example of an optical device. FIG. 9A is a top view illustrating the configuration of the LED according to this embodiment. FIG. 9B is a cross-sectional view taken along line IXb-IXb of FIG. 9A. FIG. 10A is a top view illustrating the configuration of the main part of the LED shown in FIG. 9A. FIG. 10B is a cross-sectional view taken along line Xb-Xb of FIG. 10A. Features different from the first embodiment will be mainly described below.

As shown in FIGS. 9A-10B, in the LED according to this embodiment, an LED element 51 is provided on a package substrate 8 including a plurality of leads 9. The LED element 51 includes a semiconductor substrate 4 having a top surface 4A provided with a light-emitting region 1b, a plurality of electrode pads 7 provided in a peripheral portion of the top surface 4A of the semiconductor substrate 4, and a light-transmissive insulating film 3 provided on the light-emitting region 1b. A light-transmissive member 2 is bonded to the light-emitting region 1b of the LED element 51 with a light-transmissive adhesive layer 10 interposed therebetween.

The LED according to this embodiment includes dam portions 6 described in the first embodiment. The dam portions 6 are provided outside the light-emitting region 1b, and inside the electrode pads 7 on the top surface 4A of the semiconductor substrate 4. The dam portions 6 are arranged on the top surface 4A of the semiconductor substrate 4 to interpose the light-emitting region 1b. Specifically, the dam portions 6 are provided on corners of the light-transmissive insulating film 3, which are diagonally located with respect to the light-emitting region 1b.

Each of the dam portions 6 is formed in an L shape as viewed from above. Raised portions 61 are provided on the top surfaces of the dam portions 6 at the side of the peripheral portion of the top surface 4A of the semiconductor substrate 4. Each of the raised portions 61 is located higher than the bottom surface of the light-transmissive member 2, and is formed in an L shape as viewed from above. The corners of the raised portions 61 abut on corners of the light-transmissive member 2. That is, the position of the light-transmissive member 2 is determined by the raised portions 61 of the dam portions 6. This enables the light-transmissive member 2 to be bonded to the semiconductor substrate 4 without being misaligned with respect to the light-emitting region 1b. Therefore, an LED with excellent luminous efficiency can be realized in this embodiment.

### Sixth Embodiment

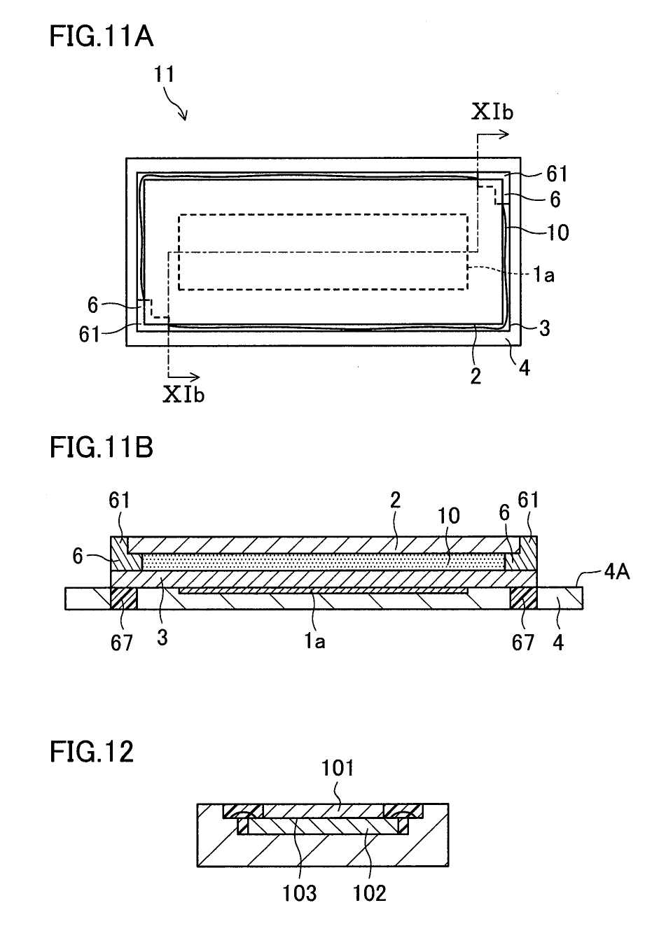

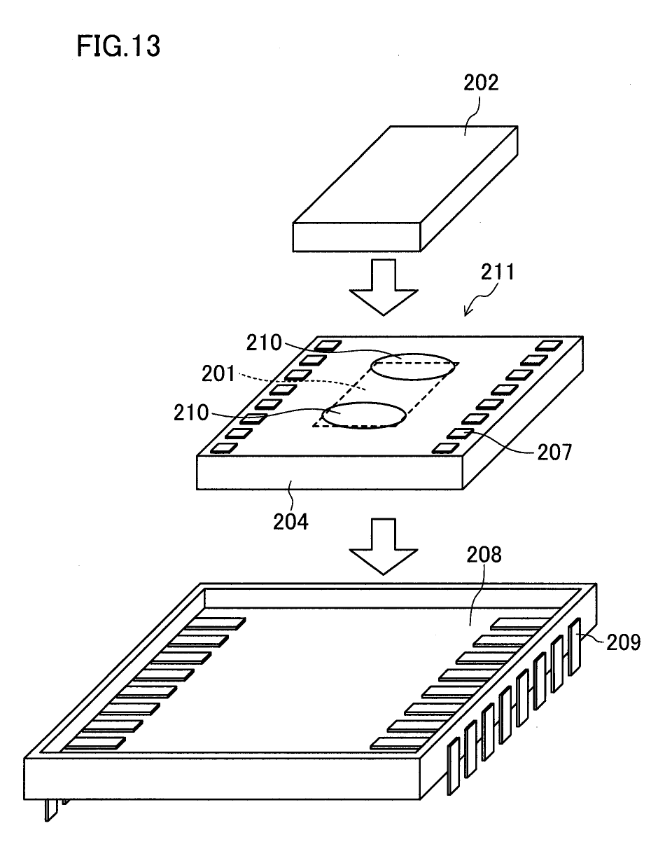

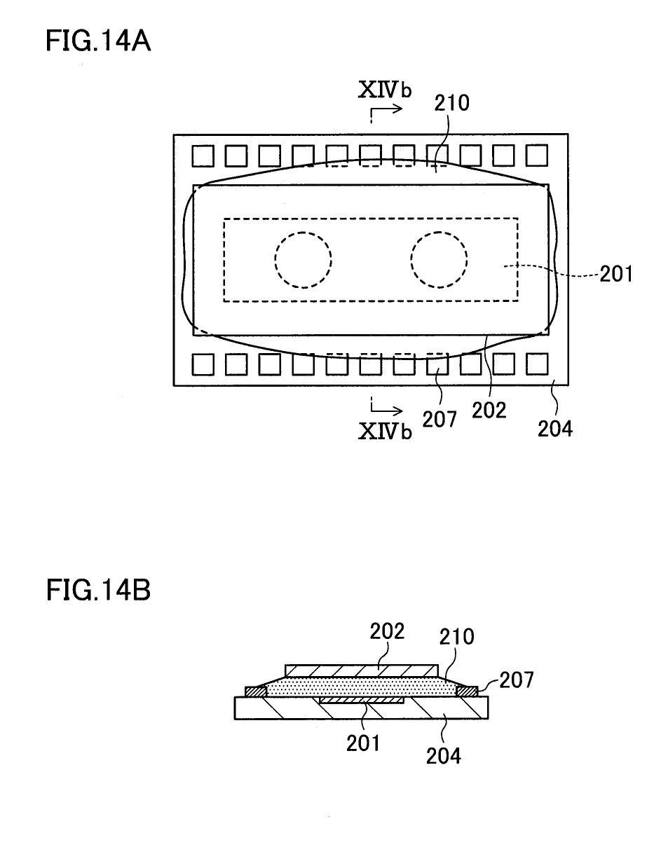

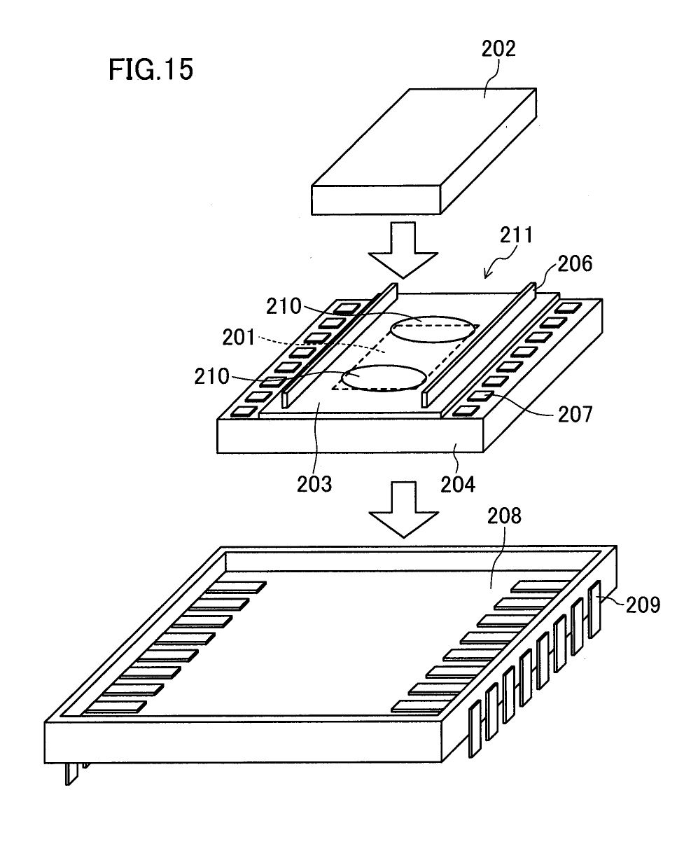

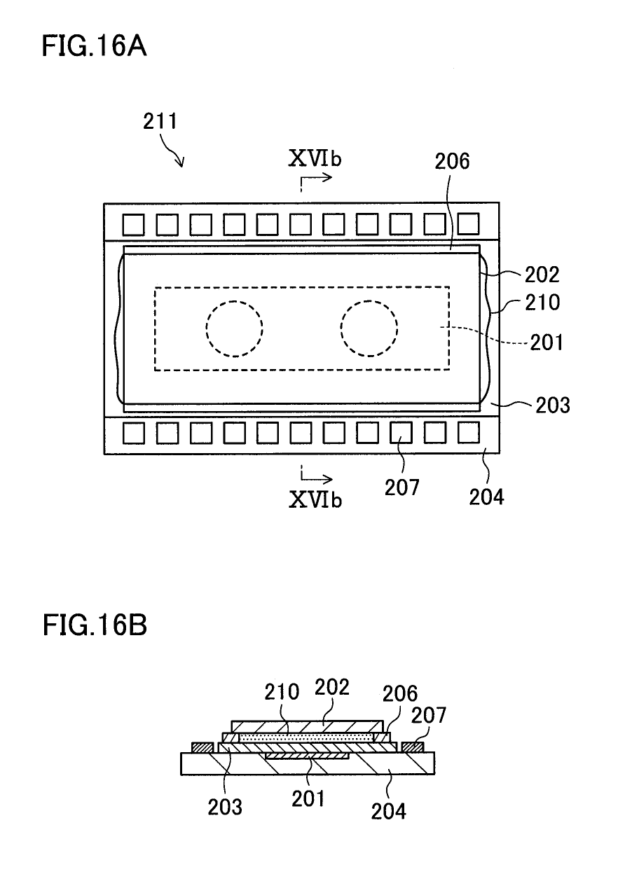

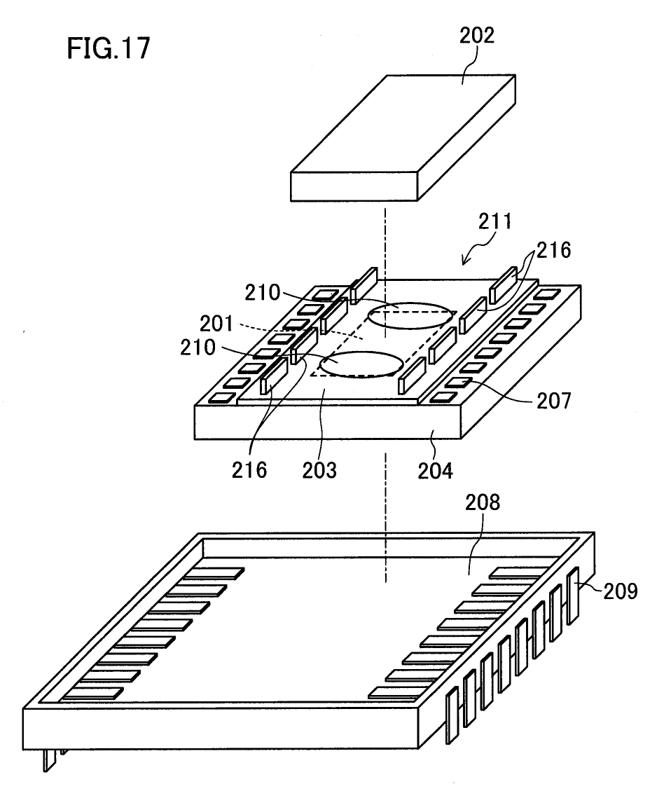

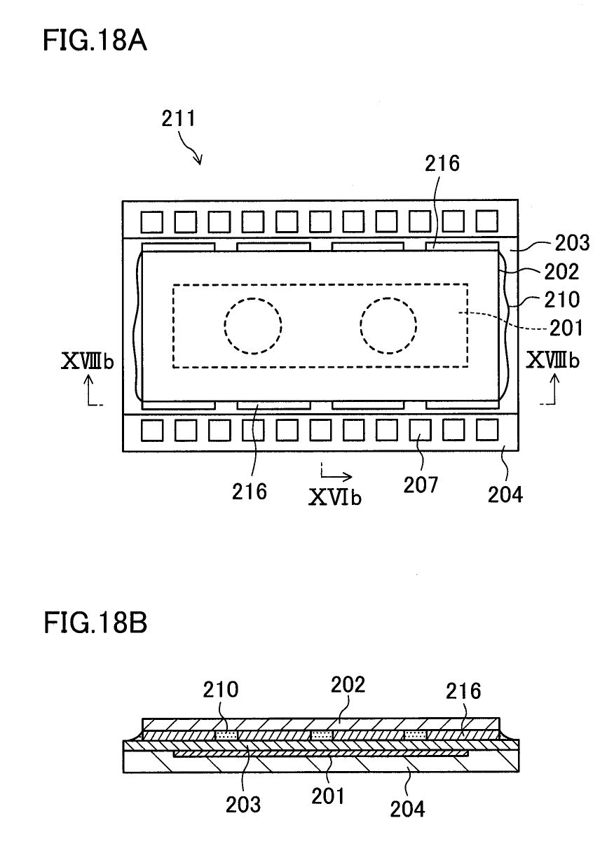

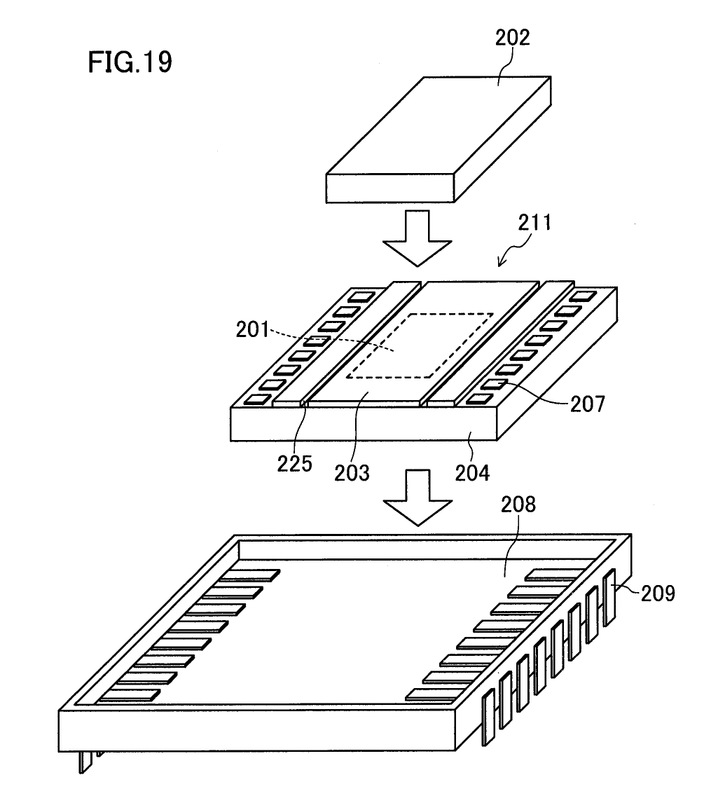

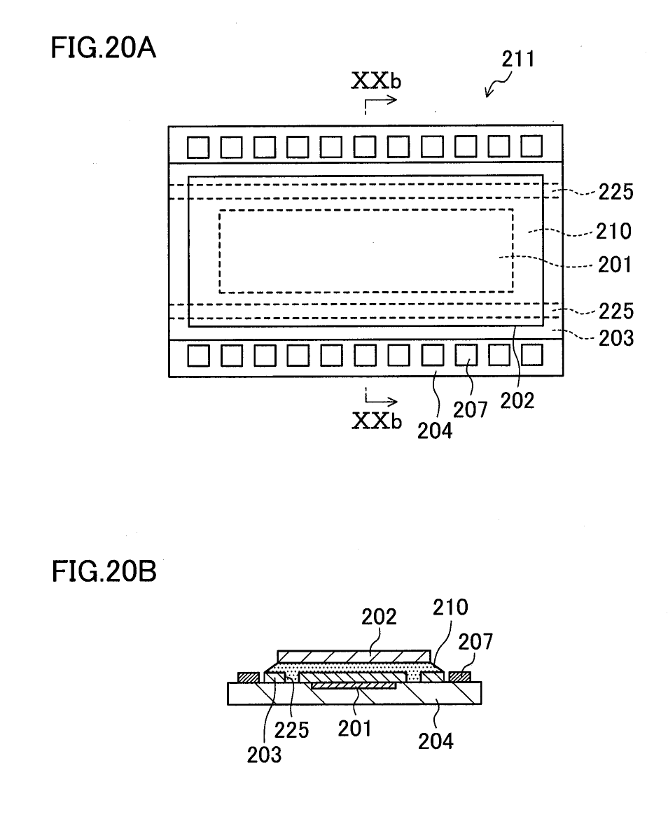

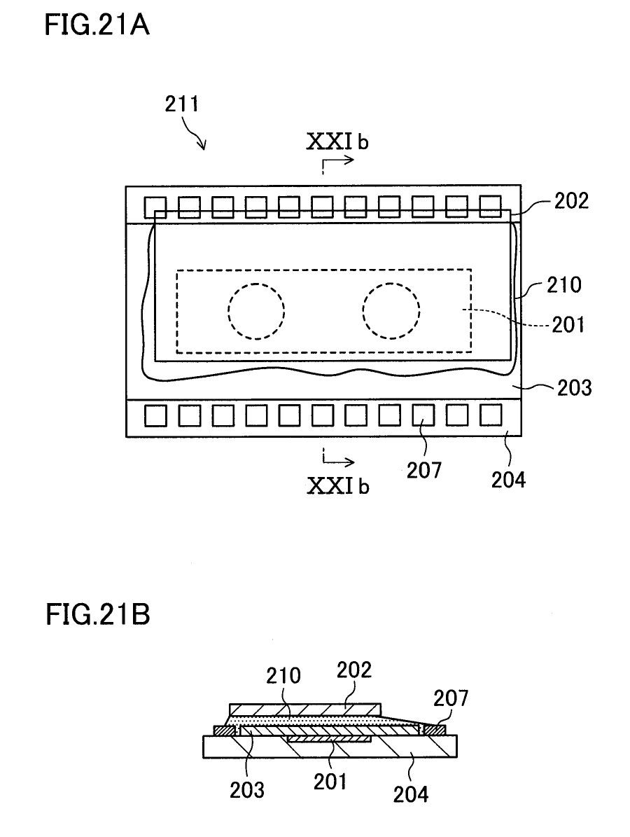

In a sixth embodiment of the present disclosure, an example will be described where through electrodes are provided instead of the electrode pads in the solid-state imaging device according to the first embodiment. FIG. 11A is a top view illustrating the configuration of the solid-state imaging device according to this embodiment. FIG. 11B is a cross-sectional view taken along line XIb-XIb of FIG. 11A. Features different from the first embodiment will be mainly described below.

The solid-state imaging device shown in FIGS. 11A and 11B includes through electrodes 67 instead of the electrode pads 7 included in the solid-state imaging device according to the first embodiment. Since the solid-state imaging device according to this embodiment includes the dam portions 6 described in the first embodiment, advantages substantially the same as those in the first embodiment can be obtained in this embodiment.

### Other Embodiments

While the solid-state imaging devices are used as optical devices in the first to fourth, and sixth embodiments, and the LED is used as an optical device in the fifth embodiment; a specific example of the optical device is not limited to a solid-state imaging device or an LED. An optical device including an image sensor (solid-state imaging element) such as a CCD or a CMOS provides similar advantages to those obtained in the first to sixth embodiments. Also, an optical device including a light-receiving element such as a photodiode, a phototransistor, or a photo IC provides similar advantages to those obtained in the first to sixth embodiments. Note that, the present disclosure is useful for increasing performance of a camera module of a digital camera, a camera module for a mobile phone, or an in-vehicle camera; when applied to the solid-state imaging devices as in the first to fourth, and sixth embodiments.

Furthermore, the present disclosure is applicable to an optical device including a light-emitting element such as an LED or a semiconductor laser. Note that the LED is used for, for example, a light-emitting display of a mobile phone or an illumination module. The semiconductor laser is preferably used in a Blu-ray disc (BD) drive, a digital versatile disc (DVD) drive, and a compact disc read-only memory (CD-ROM) drive.

The optical device of the present disclosure is useful for miniaturizing and increasing sensitivity of the optical device.

What is claimed is:

1. A optical device comprising:
a semiconductor substrate;
an element region formed on the semiconductor substrate;
at least one dam portion formed outside the element region; and
a light-transmissive board bonded to the element region with light-transmissive resin interposed therebetween, wherein
the light-transmissive board is mounted on the dam portion, and
a raised portion is formed on the dam portion.

2. The optical device of claim 1, wherein
the raised portion is fitted within a trench formed in a bottom surface of the light-transmissive board.

3. The optical device of claim 2, wherein
an electrode pad is formed outside the element region on the semiconductor substrate, and
the dam portion is provided between the element region and the electrode pad on the semiconductor substrate.

4. The optical device of claim 2, wherein
the at least one dam portion includes at least two dam portions provided on the semiconductor substrate.

5. The optical device of claim 4, wherein
the two dam portions are diagonally arranged on the semiconductor substrate as viewed from above.

6. The optical device of claim 1, wherein
a side surface of the light-transmissive board is arranged inside the raised portion.

7. The optical device of claim 6, wherein
the side surface of the light-transmissive board abuts on a side surface of the raised portion.

8. The optical device of claim 6, wherein
an electrode pad is formed outside the element region on the semiconductor substrate, and
the dam portion is provided between the element region and the electrode pad on the semiconductor substrate.

9. The optical device of claim 6, wherein
the at least one dam portion includes at least two dam portions provided on the semiconductor substrate.

10. The optical device of claim 9, wherein
the two dam portions are diagonally arranged on the semiconductor substrate as viewed from above.

11. The optical device of claim 7, wherein
the raised portion has an L shape as viewed from above.

12. A method of manufacturing an optical device comprising:
preparing a semiconductor substrate;
forming an element region on the semiconductor substrate;
forming a dam portion outside the element region; and
bonding the light-transmissive board to the element region with light-transmissive resin interposed therebetween, wherein
a raised portion is formed on the dam portion.

13. The method of claim 12, wherein
the raised portion is fitted within a trench formed in a bottom surface of the light-transmissive board.

14. The method of claim 13, wherein
an electrode pad is formed outside the element region on the semiconductor substrate, and
the dam portion is provided between the element region and the electrode pad on the semiconductor substrate.

15. The method of claim 13, wherein
the at least one dam portion includes at least two dam portions provided on the semiconductor substrate.

16. The method of claim 15, wherein
the two dam portions are diagonally arranged on the semiconductor substrate as viewed from above.

17. The method of claim 16, further comprising
curing the light-transmissive resin.

18. The method of claim 12, wherein
a side surface of the light-transmissive board is arranged inside the raised portion.

19. The method of claim 18, wherein
the side surface of the light-transmissive board abuts on a side surface of the raised portion.

20. The method of claim 18, wherein
the raised portion is formed in an L shape as viewed from above.
